(19) United States
(12) Patent Application Publication
(10) Pub. No.: US 2026/0038564 A1
(43) Pub. Date: Feb. 5, 2026

(54) APPARATUSES AND METHODS FOR ACCESS COUNT UPDATE COMMANDS

(71) Applicant: Micron Technology, Inc., Boise, ID (US)

(72) Inventor: Keisuke Nomoto, Sagamihara-shi (JP)

(73) Assignee: Micron Technology, Inc., Boise, ID (US)

(21) Appl. No.: 19/270,122

(22) Filed: Jul. 15, 2025

Related U.S. Application Data
(60) Provisional application No. 63/677,735, filed on Jul. 31, 2024.

(51) Int. Cl. G11C 11/406; G11C 11/4072; G11C 11/408; G11C 11/4096

(52) U.S. Cl. CPC G11C 11/40622; G11C 11/4072; G11C 11/4085; G11C 11/4096

(57) ABSTRACT

Embodiments of the disclosure are drawn to apparatuses, systems, and methods for performing access count update (ACU) operations based on a value of an ACU command code. A memory may activate a word line. An access count value and an ACU command code may be read from counter memory cells and ACU command memory cells associated with the active word line. Based on the value of the ACU command code, an operation may be performed on the access count value. Based on the value of the ACU command code, the access count value may be changed in a first direction, changed in a second direction, or initialized. Using the ACU command code to preserve a portion of the access count value when a word line is refreshed may decrease the likelihood of information decay.

### CROSS-REFERENCE TO RELATED APPLICATIONS

This application claims the filing benefit of U.S. Provisional Application No. 63/677,735, filed Jul. 31, 2024. This application is incorporated by reference herein in its entirety and for all purposes.

### BACKGROUND

Information may be stored on individual memory cells of the memory as a physical signal, such as a charge on a capacitive element. The memory may be a volatile memory and the physical signal may decay over time which may degrade or destroy the information stored in the memory cells. It may be necessary to periodically refresh the information in the memory cells by, for example, rewriting the information to restore the physical signal to an initial value.

As memory components have decreased in size, the density of memory cells has greatly increased. Repeated access to a particular memory cell or group of memory cells, often referred to as a “row hammer,” may cause an increased rate of data degradation in nearby memory cells. Memory devices use various schemes to identify addresses that are repeatedly accessed so that the nearby memory cells may be refreshed. One way to identify addresses that are repeatedly accessed is to keep a count of the number of accesses for a particular row. The count may need to be updated at various times or initialized to a starting value before the device begins to keep track of the number of accesses in a given time period. Memory devices may also use various schemes to update the count associated with a row so that the stored values do not cause false identification of attacks.

### BRIEF DESCRIPTION OF THE DRAWINGS

FIG. 1 is a block diagram of a semiconductor device according to at least one embodiment of the disclosure.

FIG. 2 is a block diagram of a memory cell array according to an embodiment of the present disclosure.

FIG. 3 is a block diagram of a refresh control circuit and a count control circuit according to an embodiment of the present disclosure.

FIG. 4 is a flow chart of an example access count update (ACU) operation based on an ACU command code according to some embodiments of the present disclosure.

FIG. 5 is a flow chart of an example ACU command bit setting operation according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory array includes a number of memory cells organized at the intersection of word lines, arranged as rows, and bit lines, arranged as columns. Information in the memory array may be accessed by one or more access operations, such as read or write operations. During an example access operation, a word line may be activated based on a row address. Information may be read from or written to selected memory cells along the active word line based on selected bit lines. Bit lines may be selected based on a column address. Information stored in the memory cells may decay over time. To prevent the loss of information, the memory array may periodically refresh the memory cells. For example, the memory cells may be refreshed on a row-by-row basis as part of a normal refresh and/or a self-refresh mode. The speed at which the rows are refreshed, or the maximum time any given row will go between refreshes, may be determined based on an expected rate of information decay.

Various patterns of access to a row may cause an increased rate of information decay in memory cells along nearby rows. A row experiencing such patterns of access may be called an aggressor row and the nearby rows may become victim rows. For example, a “row hammer” may involve repeated accesses to the aggressor row which may increase a rate of decay in adjacent rows and/or in rows which are farther away. This increased rate of decay, above the rate expected by the refresh timing, may risk the loss of information in the victim rows. Accordingly, some memories may track a number of accesses to each row to determine if they are aggressors so that victim rows can be identified and refreshed as part of a targeted refresh operation.

Some memories may count accesses to each row, which may be referred to as a per row activation counter (PRAC) scheme. For such a scheme, each word line has an associated access count value stored in counter memory cells along that word line. The access count value is used to determine how many times that word line has been accessed. When the word line is accessed, the access count value may be changed, for instance incremented, by a counter circuit and compared to a mitigation threshold by a comparator. If the access count value crosses the mitigation threshold, then the address may be added to an aggressor queue and during targeted refresh operations, the addresses in the queue are used to generate refresh addresses.

To change the access count value, the memory may perform an access count update (ACU) operation. For example, the memory may perform an ACU operation to iterate, such as increment, the access count value of a word line responsive to the word line being accessed. The memory may use an ACU operation to adjust the access count value in other ways. For example, after a row is refreshed, an ACU operation may be used to reduce but not clear an access count of the refreshed row in order preserve at least a portion of the access count value. The refreshed row may be an aggressor row and if nearby victim rows were not refreshed during the refresh operation, clearing the access count of the aggressor row may keep it from being identified as an aggressor row and the victim rows may not be refreshed, such as with a targeted refresh, soon enough to preserve the data they are storing.

The present disclosure is drawn to apparatuses, systems, and methods for setting an ACU command code and performing different types of ACU operations based on the ACU command code. The memory may use the ACU command code to determine what type of ACU operation to perform on an active word line. The ACU command code may be a series of digits stored along a word line in ACU command memory cells reserved for that purpose. The ACU command code may be set according to the type of ACU operation performed.

For example, a word line of a memory may be accessed. The memory may read an access count value and an ACU command code associated with the active word line. A counter control circuit may perform an action on the access count value based on the value of the ACU command code. Different actions may be performed responsive to different ACU command codes. The counter control circuit may change the ACU command code based on the action performed.

In an example implementation, the word line may be accessed responsive to an access command. Responsive to the access command, the counter control circuit of the memory may read the access count value and an ACU command code associated with the active word line. The access count value may be stored in counter memory cells associated with the active word line and the ACU command code may be stored in ACU command memory cells associated with the active word line. For example, an ACU command circuit may receive the ACU command code value, and a counter control circuit may receive the access count value. The ACU command memory cells may be one or more bits along the word line, or otherwise associated with the word line, reserved to store the ACU command code. In some embodiments, the number of ACU command memory cells may be based on a number of binary digits that make up the code. The ACU command code may be set based on the ACU operation performed. In some embodiments, the ACU command code value may be set to a different code after performing the ACU operation per the ACU command code. For example, the ACU command code may be set to a first value or normal code after performing a second type or a third type of ACU operation. In some embodiments, there may be more or fewer codes. In some embodiments, the ACU codes may be based on other settings of the memory.

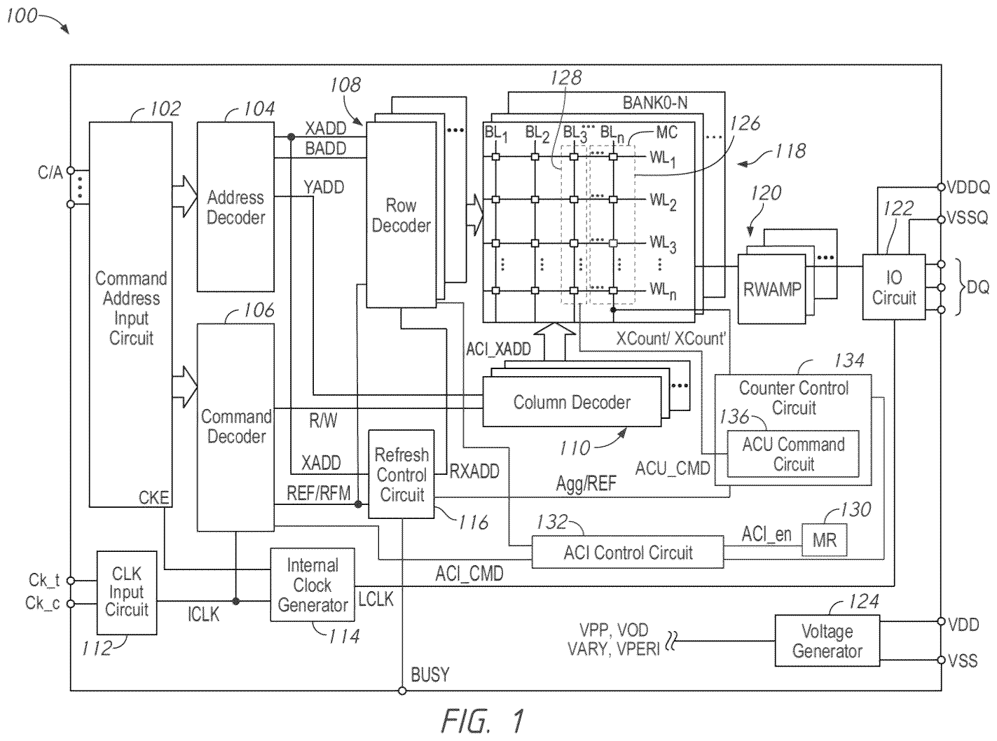

FIG. 1 is a block diagram of a semiconductor device according to at least one embodiment of the disclosure. The semiconductor device 100 may be a semiconductor memory device such as a DRAM device integrated on a single semiconductor chip.

The semiconductor device 100 includes a memory array 118. In the embodiment of FIG. 1, the memory array 118 is shown as including a number of memory banks, BANK0 to BANKN. For example, the memory may include 4 banks, 8 banks, or 16 banks. More or fewer banks may be included in the memory array 118 of other embodiments. Each memory bank includes a plurality of word lines WL or rows, a plurality of bit lines BL or columns, and a plurality of memory cells MC arranged at intersections of the plurality of word lines WL and the plurality of bit lines BL.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (not shown in FIG. 1). Read data from the bit line BL is amplified by the sense amplifier and transferred to read/write amplifiers 120 over complementary local data lines, transfer gate, and complementary main data lines. Conversely, write data outputted from the read/write amplifiers 120 is transferred to the sense amplifier over the complementary main data lines, the transfer gate, and the complementary local data lines, and written in the memory cell MC coupled to the bit line BL.

Some of the memory cells may be set aside as counter memory cells 126. The counter memory cells 126 may store access count values XCount, each of which is associated with one of the word lines WL. Each access count value XCount may be stored in counter memory cells 126 along the word line WL with which the access count value XCount is associated. The access count value XCount may be stored as a binary number with each bit stored in a memory cell along the word line WL. For the sake of clarity, a single bit line of counter memory cells 126 is shown in FIG. 1. The number of counter memory cells 126 along each word line may be based on a number of bits of the access count value XCount. Extra counter memory cells 126, for instance more than the length of the number XCount, may be used. For example, extra counter memory cells 126 may store error correction information for the access count value XCount.

The counter memory cells 126 may be referred to as such because they are used for storing the access count values. The counter memory cells 126 may be structurally similar to, or identical to, the other memory cells of the array. The counter memory cells 126 may be grouped together, such as at the end of the word line WL. The counter memory cells 126 may be coupled along the same bit lines BL, which may be referred to as counter bit lines. Other distributions of the counter memory cells 126 along the word line WL may be used or the counter memory cells 126 may be otherwise associated with the word line WL. The counter memory cells 126 may not be directly accessible by external devices such as controllers. The lack of direct access by external devices may be to prevent the access count values from being overwritten, for example. In other words, the counter bit lines may not be directly accessed by a normal column address.

Some of the memory cells may be set aside as ACU command memory cells 128. The ACU command memory cells 128 may store an ACU command code ACU_CMD each of which is associated with one of the word lines WL. Each ACU command code ACU_CMD may be stored in ACU command memory cells 128 along the word line WL with which the ACU command code ACU_CMD is associated. The ACU command code ACU_CMD may be stored as a series of binary digits with each digit stored in a memory cell along the word line WL. For the sake of clarity, a single bit line of ACU command memory cells 128 is shown in FIG. 1. The number of ACU command memory cells 128 along each word line may be based on a number of bits of the ACU command code ACU_CMD which may be based on the number of different types of ACU operations.

The ACU command memory cells 128 may be referred to as such because they are used for storing the value of the ACU command code ACU_CMD. The ACU command memory cells 128 may be structurally similar to, or identical to, the other memory cells of the array. The ACU command memory cells 128 may be grouped together, such as at the end of the word line WL. The ACU command memory cells 128 may be coupled along the same bit lines BL, which may be referred to as ACU bit lines. Other distributions of the ACU command memory cells 128 along the word line WL may be used or the ACU command memory cells 128 may be otherwise associated with the word line WL. The ACU command memory cells 128 may not be directly accessible by external devices such as controllers. The lack of direct access by external devices may be to prevent the ACU command codes from being overwritten, for example. In other words, the ACU bit lines may not be directly accessed by a normal column address.

The semiconductor device 100 may employ a plurality of external terminals to send and receive external signals. The plurality of external terminals include command and address C/A terminals coupled to a command and address bus to receive commands and addresses and a CS signal, clock terminals to receive clocks CK and/CK, data terminals DQ to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The internal clock ICLK is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line. When an access command is received, the command decoder 106 provides a row activation signal ACT, which activates the word line specified by the row address. At the end of an access operation, the command decoder 106 provides a pre-charge signal Pre, which pre-charges or deactivates the word line. When a row is activated, its access count value XCount and the value of its ACU command code ACU_CMD are read out along the counter bit lines to a counter control circuit 134, which performs an ACU operation that updates the access count value XCount according to the value of the ACU command code ACU_CMD and writes the updated access count value XCount′ back to the counter memory cells along the active word line.

The semiconductor device 100 may receive an access command which is a read command. When a read command is received, a bank address BADD and a column address YADD are timely supplied with the read command, read data is read from memory cells in the memory array 118 corresponding to the row address XADD and column address YADD. The read command is received by the command decoder 106, which provides internal commands so that read data from the memory array 118 is provided to the read/write amplifiers 120. The row decoder 108 activates the word line indicated by XADD, and the information in the memory cells along that word line is read out to their respective bit lines. While the word line is activated, the access count value XCount and the value of the ACU command code ACU_CMD are read out to the counter control circuit 134, which updates the access count value XCount according to the value of the ACU command code ACU_CMD and writes the updated access count value XCount′ back to the counter memory cells along the active word line. In some embodiments, the counter control circuit 134 may be configured to decrement a decrement value from the access count value XCount when the word line is accessed and then iterate the access count value XCount when the word line is next accessed. The counter control circuit 134 may change the ACU for the next activation of a word line by setting the ACU command code. The column decoder 110 provides a column select signal based on YADD which couples selected bit lines to the read/write amplifiers 120. A time after providing the activation signal, the row decoder 108 provides a pre-charge signal to deactivate the word line. The read data is outputted to outside from the data terminals DQ via the input/output circuit 122.

The semiconductor device 100 may receive an access command which is a write command. When the write command is received, a bank address BADD and a column address YADD are timely supplied with the write command, write data supplied to the data terminals DQ is written to memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. The row decoder 108 provides the activation signal to the word line indicated by XADD, which causes the values in the memory cells along the active word line to be read out to their respective bit lines. The access count value XCount and the value of the ACU command code ACU_CMD along the activated word line are read out to the counter control circuit 134 which updates the access count value XCount according to the value of the ACU command code ACU_CMD and writes the updated access count value XCount′ back to the counter memory cells 126. The column decoder 110 provides a column select signal based on YADD and couples selected bit lines to the read/write amplifiers 120, which write the write data onto the selected bit lines. A time after activating the row, the row decoder 108 provides a pre-charge signal and deactivates the word line.

The semiconductor device 100 may also receive commands causing it to carry out refresh operations. For example, a controller of the memory may put the semiconductor device 100 into a normal refresh mode and provide a refresh command. Responsive to the refresh command, the command decoder 106 provides a refresh signal REF. The semiconductor device 100 may also enter a self-refresh mode where the refresh signal REF is generated internally.

Responsive to the refresh signal REF, the refresh control circuit 116 performs one or more refresh operations by providing a refresh address RXADD, along with refresh signals (not shown in FIG. 1) to the row decoder 108. The row decoder 108 refreshes the word line(s) associated with the refresh address RXADD, for example by restoring a charge in the memory cells along the word line(s) to an initial value associated with the value of the bit stored in that memory cell.

When the refresh control circuit 116 performs refresh operations responsive to REF, it determines if the refresh operations are normal refresh operations, targeted refresh operations, or combinations thereof. In a normal refresh operation, the refresh address RXADD is generated based on a sequence of addresses. In other words, the refresh address RXADD may be generated based on a previous value of the refresh address. For example, RXADD(i)=RXADD(i−1)+1. The sequence logic used to generate the normal refresh addresses may cycle through each of the word lines of the memory array 118. For instance, the refresh control circuit 116 may include an address counter and an address mapping circuit. The address counter may count through a sequence of values and the address mapping circuit may generate the refresh address RXADD based on the position of the count in the sequence.

In a targeted refresh operation, the refresh address RXADD is generated based on an identified aggressor address stored in a targeted refresh queue of the refresh control circuit 116. The refresh address RXADD may represent victim addresses, which may be associated with word lines that have a spatial relationship with the word line associated with the identified aggressor address. For example, the refresh address RXADD may be word lines adjacent to the aggressor word line (e.g., RXADD=Aggressor+/−1). Other relationships (e.g., +/−2, +/−3, +/−4, etc.) may also be used.

In some embodiments, the normal refresh address may be associated with a different number of word lines than the targeted refresh address. The normal refresh address may be associated with more word lines than the targeted refresh address. For example, the normal refresh address may be truncated compared to a row address XADD and be associated with all the word lines whose addresses share the value of that truncated portion in common, while the targeted refresh address may be associated with a single word line.

The counter control circuit 134 may act as an aggressor detection circuit, which tells the refresh control circuit 116 if the current row address XADD is associated with an aggressor word line or not. For example, if the updated access count value XCount from the currently active word line crosses a mitigation threshold, then the counter control circuit 134 may provide an aggressor detected signal Agg to the refresh control circuit 116. Responsive to the aggressor detected signal Agg, the refresh control circuit 116 adds the current row address XADD to the targeted refresh queue. The counter control circuit 134 may include a comparator which compares the updated access count value XCount to the mitigation threshold. Alternatively, the counter control circuit 134 may inherently act as a comparator. For example, the threshold may represent the maximum value of the access count value XCount and when the access count value XCount reaches a maximum value and “rolls over” back to an initial value, the counter control circuit 134 provides an aggressor detected signal Agg.

Responsive to a refresh signal REF, the ACU command circuit 136, which may be included in the counter control circuit 134, may set the ACU command memory cells 128 associated with the refreshed word line(s) WL to an ACU command code ACU_CMD. The value of the ACU command code ACU_CMD may be received by the counter control circuit while the word line(s) WL associated with the ACU command memory cells 128 is active, such as responsive to an access command ACT or a pre-charge command PRE. Based on the value of the ACU command code ACU_CMD, the counter control circuit 134 perform an operation on the access count value XCount stored in the counter memory cells 126. In some embodiments, the value of the ACU command code ACU_CMD may indicate that the counter control circuit change the access count value XCount in a first direction or a second direction and write the new access count value XCount′ back to the counter memory cells 126. For example, the value of the ACU command code ACU_CMD may indicate to decrement the access count value XCount. In some embodiments, this value of the ACU command code ACU_CMD may be a refresh code because the ACU command circuit 136 may set the ACU command memory cells 128 to the refresh code responsive to the memory device 100 performing a refresh operation on the word line associated with the ACU command memory cells 128. In some embodiments, the value of the ACU command code ACU_CMD may indicate to increment the access count value XCount. For example, this value of ACU command code ACU_CMD may be a normal code because the ACU command code ACU_CMD may set the ACU command memory cells 128 to the normal code when the memory device 100 is operating normally, as in the memory device 100 is not performing a refresh operation or in an activation count initialization (ACI) mode.

A controller of the memory may put the semiconductor device 100 into an ACI mode and, if applicable, provide the ACI command. In some embodiments, the semiconductor device 100 may enter an ACI mode automatically, such as after power up. In order to perform ACI operations, such as based on an ACI command or based on internal timing, the command decoder 106 provides an ACI command signal ACI_CMD. Responsive to the ACI command signal ACI_CMD, the ACI control circuit 132 performs one or more ACI operations by providing an ACI address ACI_XADD, along with other ACI signals (not shown in FIG. 1) to the row decoder 108 and by providing ACI signals ACI to the counter control circuit 134. The row decoder 108 activates the word line(s) associated with the ACI address ACI_XADD.

In some embodiments, during an ACI mode, the device 100 may set ACU command memory cells 128 to indicate a state of the access counts XCount of the memory array 118. For example, during an ACI mode, the counter control circuit 134 may set the ACU command memory cells 128 to indicate that the counter memory cells 126 are ready to receive an initialization value, such as when the counter memory cells 126 are in an unknown state. This state may be associated with an ACU command code ACU_CMD, such as an initialization code. In some embodiments, there may be three ACU command codes associated with each word line WL. In yet other embodiments, there may be more or fewer ACU command codes.

The semiconductor device 100 includes one or more registers where information and/or settings of the semiconductor device 100 are stored. FIG. 1 shows a mode register 130, which includes a number of registers which may be used to store settings, properties, measured quantities, etc. related to the operation of the semiconductor device 100. For example, an ACI register of the mode register 130 may have a value which indicates if the device is in the ACI mode or not.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

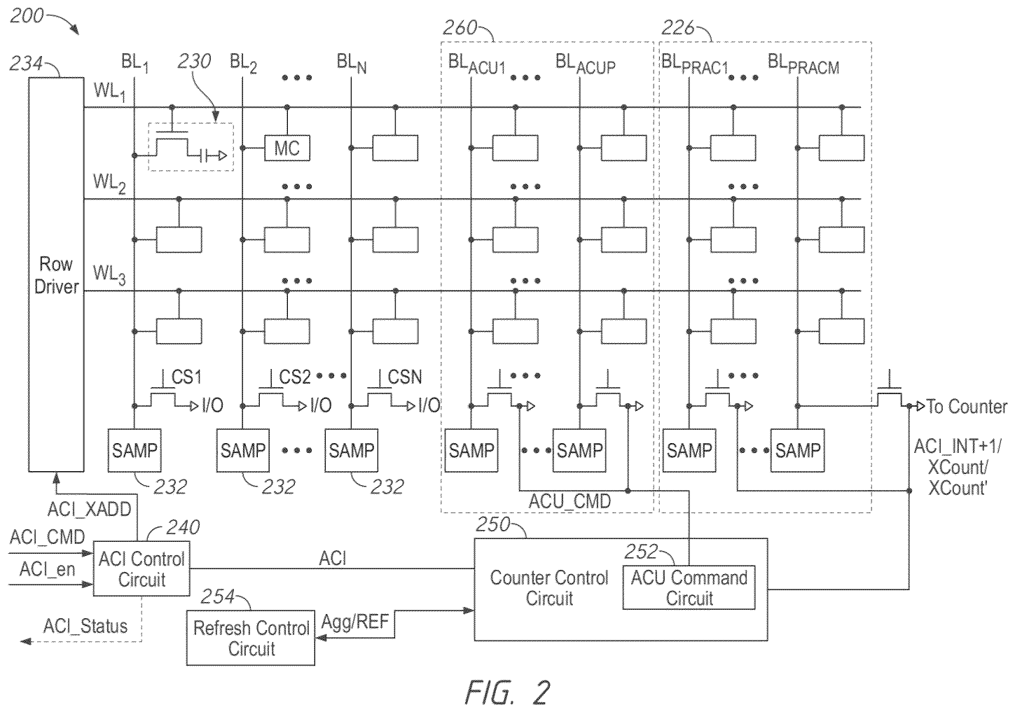

FIG. 2 is a block diagram of a memory cell array according to an embodiment of the present disclosure. The memory cell array 200 may represent an exemplary portion of a memory array, such as the memory array 118 of FIG. 1. The memory cell array 200 includes a plurality of word lines WL, or rows, and bit lines BL, or columns. A row decoder 234 (e.g., row decoder 108 of FIG. 1) is coupled to the rows. A plurality of memory cells MC, such as example memory cell 230, are located at the intersection of the rows and columns. Some of the memory cells may be set aside as counter memory cells 226 (e.g., counter memory cells 126 of FIG. 1). Some of the memory cells may be set aside as ACU command memory cells 260 (e.g., ACU command memory cells 128 of FIG. 1). The memory array 200 includes a number of sense amplifiers 232.

Each of the memory cells MC may store information. In some embodiments, the information may be stored as a binary code and each memory cell MC may store a bit that may be either at a logical high or a logical low level. Example memory cell 230 shows a particular implementation which may be used to store a bit of information in some embodiments. Other types of memory cells may be used in other examples. In the example memory cell 230, a capacitive element stores the bit of information as a charge. A first charge level may represent a logical high level, while a second charge level may represent a logical low level. One node of the capacitive element is coupled to a reference voltage (e.g., VSS). The other node of the capacitive element is coupled to a switch. In the example memory cell 230, the switch is implemented using a transistor. A sense node of the switch, such as the gate of the transistor, is coupled to the word line WL. The word line WL may be accessed by the row driver 234 setting a voltage along the word line such that the switches in the memory cells MC are closed, coupling the capacitive elements, or other bit storage element, to the associated bit lines BL.

The sense amplifiers 232 may read or write a value of a bit of information along the bit line BL to memory cell(s) MC at the accessed word line WL. The sense amplifiers 232 may convert a signal along the bit line BL to a signal which is “readable” by other elements of the memory device, such as by amplifying a voltage. The bit lines BL may be coupled to an input/output circuit (e.g., input/output circuit 122 of FIG. 1) via a respective column select switch, which may be a column select transistor activated by a column select signal CS. In the example view of FIG. 2, bit lines BL₁-BL_{N} are “normal” bit lines each accessed by a respective column select signal CS1 to CSN. Bit lines BL_{ACU1}-BL_{ACUP} are associated with the ACU command memory cells 260. Bit lines BL_{PRAC1}-BL_{PRACM} are associated with the counter memory cells 226. Accordingly, each word line WL of FIG. 2 stores N+P+M total bits, P of which are designated for ACU command memory cells to store an ACU command code (e.g., ACU_CMD of FIG. 1) and M of which are designated for counter memory cells to store an access count value (e.g., XCount of FIG. 1). It should be understood that FIG. 2 is a simplified view and that many more (or fewer) memory cells and/or a different ratio of normal memory cells to ACU command memory cells 260 and counter memory cells 226 may be used.

In an example read operation, when a word line WL is accessed, the memory cells MC may provide their charge onto the coupled bit lines BL which may cause a change in a voltage and/or current along the bit line BL. The sense amplifier 232 may determine a logical level of the accessed memory cell MC based on the resulting voltage and/or current along the bit line BL and may provide a signal corresponding to the logical level through the column select transistor to the input/output circuit.

In an example write operation, the sense amplifiers 232 may receive a signal indicating a logical level to be written to the accessed memory cells from the input/output circuit. The sense amplifier 232 may provide a voltage and/or current along the coupled bit line BL, such as along the bit lines BL with active column select transistors, at a level corresponding to the logical level to be written. The voltage and/or current along the bit line BL may charge the capacitive element at the intersection of the bit line BL with an accessed word line WL to a charge level associated with the written logical level. In this manner, by specifying the row which is accessed and which bit lines BL to record data from (and/or write data to), specific memory cells MC may be accessed during one or more operations of the memory device.

During an example refresh operation, either targeted or normal refresh, the word line WL to be refreshed may be read and then a logical value read from each of the memory cells along that word line WL may be written back to the same memory cells. In this manner the level of charge in the refreshed memory cells MC may be restored to the full value associated with the logical level stored in that memory cell.

Responsive to a normal refresh operation, the counter control circuit 250 provides an ACU command code ACU_CMD to the sense amplifier 232 coupled to the ACU command bits 260. The sense amplifier 232 drives the ACU command code ACU_CMD on to the ACU command memory cells 260 of the active word lines WL. In some embodiments, responsive to the refresh signal, the counter control circuit 250 may provide a value of ACU command code ACU_CMD to the active word lines WL that indicates that the access count value XCount be changed in a first direction when the word lines WL are next accessed. For example, the value of the ACU command code ACU_CMD may indicate that a decrement value, such as a preset discrete number, is to be decremented from the access count value XCount stored in the counter memory cells 226 (e.g., 126 of FIG. 1) associated with the word lines WL when the word lines WL are next accessed. The amount subtracted from the access count value XCount may be a predetermined amount. Responsive to the activation of the word line, the counter control circuit 250 (e.g., 126 of FIG. 1) may iterate the decremented access count value such as by incrementing it and cause the updated access count value XCount′ to be written to the counter memory cells 226 (e.g., 126 of FIG. 1) of the active word line. An address counter may be coupled with the refresh control circuit 254 (e.g., 116 of FIG. 1) that provides the refresh address (e.g., RXADD of FIG. 1) to the row decoder 234.

During an example ACI mode, an ACI control circuit 240 (e.g., ACI control circuit 132 of FIG. 1) receives an ACI command signal ACI_CMD. In some embodiments the ACI_CMD may be received along with an ACI enable signal ACI_en. The ACI enable signal ACI_en indicates if the memory device is in an ACI mode or not. For example, the ACI enable signal ACI_en may be provided by a mode register such as 130 of FIG. 1. The ACI command signal ACI_CMD may be provided by a command decoder such as 106 of FIG. 1. In some embodiments, the ACI command signal ACI_CMD may be a command used for another purpose outside the ACI mode, such as a refresh command, which is interpreted as an ACI command when the device is in the ACI mode, such as when ACI_en is active.

Responsive to the ACI command signal ACI_CMD and when the enable signal ACI_en is active, the ACI control circuit 240 performs an ACI operation by providing an ACI address ACI_XADD, along with ACI signals (not shown in FIG. 2), to the row decoder 234. The row decoder 234 activates the word line(s) WL associated with the ACI address ACI_XADD. Also, responsive to the ACI command signal ACI_CMD when the enable signal ACI_en is active, the ACI control circuit 240 performs an ACI operation by providing an ACI signal ACI to the counter control circuit 250 (e.g., 134 of FIG. 1). Responsive to the ACI signal ACI, the counter control circuit 250 provides the ACU command code ACU_CMD to the sense amplifier 232 coupled to the ACU command memory cells 260 (e.g., 128 of FIG. 1). The sense amplifier 232 drives the ACU command code ACU_CMD on to the ACU command memory cells 260 (e.g., 128 of FIG. 1) of the active word lines WL. The value of the ACU command code ACU_CMD provided during an ACI mode may be different than the value of the ACU command code ACU_CMD provided responsive to a refresh operation. For example, responsive to the ACI signal, the counter control circuit 250 (e.g., 134 of FIG. 1) may provide an ACU command ACU_CMD to the active word lines WL that indicates that counter memory cells 226 (e.g., 126 of FIG. 1) associated with the word lines WL are ready to be initialized when the word lines WL are next accessed. An address counter may be coupled with the ACI control circuit 240 (e.g., 132 of FIG. 1) that provides the ACI address to the row decoder 234. The address counter may be a component that is shared with an existing system, such as the refresh control circuit. For example, the address counter may be an address counter which is used to generate refresh addresses when the device is not in the ACI mode.

In some embodiments, the counter control circuit 250 (e.g., 134 of FIG. 1) may include an ACU command circuit 252 (e.g., 136 of FIG. 1) to set the ACU command memory cells 260 (e.g., 128 of FIG. 1). The ACU command circuit 252 (e.g., 136 of FIG. 1), responsive to an access command such as an activation command ACT or a pre-charge command PRE, may receive the value of the ACU command code ACU_CMD stored in the ACU command memory cells 260 (e.g., 128 of FIG. 1) associated with the word line WL accessed by the access command. If the value stored in the ACU command memory cells 260 (e.g., 128 of FIG. 1) matches an initialization command value, the counter control circuit 250 (e.g., 134 of FIG. 1) will write an initialization value ACI_INT to the counter memory cells 226 (e.g., 126 of FIG. 1). If the value stored in the ACU command bits 260 (e.g., 128 of FIG. 1) does not equal the initialization code, the counter control circuit 250 may perform another operation on the access count value XCount. For example, the counter control circuit 250 (e.g., 134 of FIG. 1) may change the access count value XCount in a first direction based on the ACU command code ACU_CMD or the counter control circuit 250 (e.g., 134 of FIG. 1) may change the access count value XCount in a second direction based on another value of the ACU command code ACU_CMD and write the updated access count value XCount′ back to the counter memory cells 226 (e.g., 126 of FIG. 1).

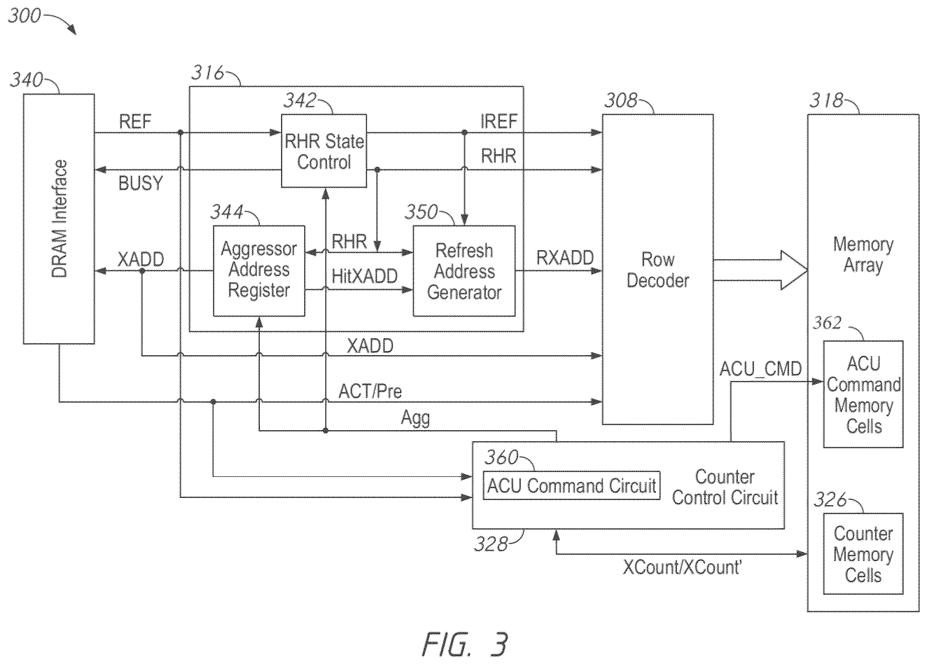

FIG. 3 is a block diagram of a refresh control circuit and a counter control circuit according to an embodiment of the present disclosure. For context, a row decoder 308, a DRAM interface 340, and a memory array 318 are also shown. In some embodiments, the refresh control circuit 316 may be used to implement the refresh control circuit 116 of FIG. 1 and/or 254 of FIG. 2. Similarly, the row decoder 308 may be used to implement the row decoder circuit 108 of FIG. 1, the memory array 318 may be used to implement memory array 118 of FIG. 1, and the counter control circuit 328 may be used to implement the counter control circuit 134 of FIG. 1. Certain internal components and signals of the refresh control circuit 316 are shown to illustrate the operation of the refresh control circuit 316. The dotted line around the refresh control circuit 316, the row decoder 308, counter control circuit 328, and the memory array 318 is shown to represent that in certain embodiments, each of the components within the dotted line may correspond to a particular bank of memory (e.g., memory banks BANK0-N of memory array 118) and that these components may be repeated for each of the banks of memory. In some embodiments, the components shown within the dotted line may be associated with each of the memory banks. Thus, there may be multiple refresh control circuits 316, counter control circuits 328, and row decoders 308. For the sake of brevity, components for only a single bank will be described. Further, in some embodiments one or more of the components may be shared between banks.

A DRAM interface 340 may provide one or more signals to the address refresh control circuit 316 and row decoder 308 which in turn (along with a column decoder, not shown) may perform access operations on the memory array 318. The DRAM interface 340 may represent one or more components which provides signals to components of the bank. In some embodiments, the DRAM interface 340 may include a memory controller coupled to the semiconductor memory device. In some embodiments, the DRAM interface 340 may represent one or more components of a semiconductor device (e.g., device 100 of FIG. 1) such as the command address input circuit 102, the address decoder 104, and/or the command decoder circuit 106 of FIG. 1. The DRAM interface 340 may provide a row address XADD, the refresh signal REF, an activation signal ACT, and a pre-charge signal Pre. The refresh signal REF may be a periodic signal which may indicate when a refresh operation is to occur. The activation signal ACT may be provided to activate a given bank of the memory. The pre-charge signal Pre may be provided to pre-charge the given bank of the memory. The row address XADD may be a signal which specifies one or more particular word lines of the memory array 318 and may be a signal including multiple bits (which may be transmitted in series or in parallel).

The counter control circuit 328 (e.g., 134 of FIG. 1 and/or 250 of FIG. 2) may be coupled to the memory array 318, particularly, to the counter memory cells 326 of the memory array 318. The counter memory cells 326 may be used to implement the counter memory cells 126 of FIG. 1 and/or 226 of FIG. 2 in some embodiments. The counter control circuit 328 may also be coupled to ACU command memory cells 362 of the memory array 318. In some embodiments, the ACU command memory cells 362 may be used to implement the ACU command memory cells 128 of FIG. 1 and/or 260 of FIG. 2.

When a word line of the memory array 318 (e.g., 118 of FIG. 1 and/or 200 of FIG. 2) is accessed, the access count value XCount of the counter memory cells 326 (e.g., 126 of FIG. 1 and/or 226 of FIG. 2) and the ACU command code ACU_CMD of the ACU command memory cells 362 (e.g., 128 of FIG. 1 and/or 260 of FIG. 2) associated with that word line are read to the counter control circuit 328 (e.g., 134 of FIG. 1 and/or 250 of FIG. 2). The counter control circuit 328 (e.g., 134 of FIG. 1 and/or 250 of FIG. 2) may include an ACU command circuit 360. In some embodiments, the ACU command circuit 360 may implement the ACU command circuit 136 of FIG. 1 and/or 252 of FIG. 2. The ACU command circuit 360 (e.g., 136 of FIG. 1 and/or 252 of FIG. 2), responsive to an access command such as an activation command ACT or a pre-charge command PRE, may receive the ACU command code ACU_CMD stored in the ACU command memory cells 362 (e.g., 128 of FIG. 1 and/or 260 of FIG. 2) associated with the word line WL accessed by the access command. The ACU command circuit 360 (e.g., 136 of FIG. 1 and/or 252 of FIG. 2) may cause the counter control circuit 328 (e.g., 134 of FIG. 1 and/or 250 of FIG. 2) to perform an ACU operation on the access count value XCount according to the value of the ACU command code ACU_CMD. In some embodiments, the counter control circuit 328 (e.g., 134 of FIG. 1 and/or 250 of FIG. 2) may change the access count value XCount in a first direction based on a first value of ACU command code ACU_CMD or the counter control circuit 328 (e.g., 134 of FIG. 1 and/or 250 of FIG. 2) may change the access count value XCount in a second direction based on a second value of ACU command code ACU_CMD. For example, the counter control circuit 328 (e.g., 134 of FIG. 1 and/or 250 of FIG. 2) may increment the access count value XCount based on the first value of ACU command code ACU_CMD being a normal ACU command code or the counter control circuit 328 (e.g., 134 of FIG. 1 and/or 250 of FIG. 2) may decrement the access count value XCount based on the second value of ACU command code ACU_CMD being a refresh command code. The counter control circuit 328 (e.g., 134 of FIG. 1 and/or 250 of FIG. 2) may write the updated access count value XCount′ back to the counter memory cells 326 (e.g., 126 of FIG. 1 and/or 226 of FIG. 2).

The ACU command circuit 360 (e.g., 136 of FIG. 1 and/or 252 of FIG. 2) may set the ACU command code ACU_CMD in the ACU command memory cells 362 (e.g., 128 of FIG. 1 and/or 260 of FIG. 2) to a different value of ACU command code ACU_CMD after the counter control circuit 328 (e.g., 134 of FIG. 1 and/or 250 of FIG. 2) performs the ACU operation on the access count value XCount. In some embodiments, if the counter control circuit 328 (e.g., 134 of FIG. 1 and/or 250 of FIG. 2) performs a second type of ACU operation on the access count value XCount based on the value of ACU command code ACU_CMD being a second value, the ACU command circuit 360 (e.g., 136 of FIG. 1 and/or 252 of FIG. 2) may set the ACU command code ACU_CMD in the ACU command memory cells 362 (e.g., 128 of FIG. 1 and/or 260 of FIG. 2) to a first value of ACU command code. For example, if the count control circuit 328 (e.g., 134 of FIG. 1 and/or 250 of FIG. 2) performs a decrement type of ACU operation on the access count value XCount based on the ACU command code ACU_CMD being a refresh type of code because the associated word line was refreshed since it was last accessed, the ACU command circuit 360 (e.g., 136 of FIG. 1 and/or 252 of FIG. 2) may set the ACU command code ACU_CMD in the ACU command memory cells 362 (e.g., 128 of FIG. 1 and/or 260 of FIG. 2) to a normal type of ACU command code to indicate to the counter control circuit 328 (e.g., 134 of FIG. 1 and/or 250 of FIG. 2) to increment the access count value XCount when the word line is next accessed.

The counter control circuit 328 (e.g., 134 of FIG. 1 and/or 250 of FIG. 2) may determine if the access count value XCount for the word line is greater than a threshold value or is equal to a threshold value. If the access count value XCount is not equal to or does not exceed the threshold, in other words if the value is less than the threshold, then the counter control circuit 328 (e.g., 134 of FIG. 1 and/or 250 of FIG. 2) may perform an ACU operation on the access count value XCount according to the value of the ACU command code ACU_CMD and write the updated count value XCount′ back to the count value memory cells 326 (e.g., 126 of FIG. 1 and/or 226 of FIG. 2). Updating the count may include incrementing or decrementing the count in some embodiments based on the value of ACU command code ACU_CMD. If the access count value XCount does equal or exceed the threshold, then the current address XADD may be determined to be an aggressor address. If the current address XADD is an aggressor address, an active aggressor row detection signal Agg may be provided to the refresh control circuit 316 (e.g., 116 of FIG. 1 and/or 254 of FIG. 2), which may record, or latch, the current value of the row address XADD. The active aggressor row detection signal Agg may further trigger a targeted refresh operation. If the value of the count exceeds the threshold, then the counter control circuit 328 (e.g., 134 of FIG. 1 and/or 250 of FIG. 2) may reset a value of the count, for example, by writing an initial value of the count (e.g., 0) back to the access count memory cells 326 (e.g., 126 of FIG. 1 and/or 226 of FIG. 2).

The counter control circuit 328 (e.g., 134 of FIG. 1 and/or 250 of FIG. 2) may further update the value of the count responsive to the passage of a period of time over which the word line is activated. For example, the counter control circuit 328 (e.g., 134 of FIG. 1 and/or 250 of FIG. 2) may update the count value every time some number of nanoseconds has passed and/or each time a clock/timer signal is oscillated. The updated value of the count may be compared to the threshold value as described above after each update of the count value, such as after each period of time the word line remains activated. Various techniques may be used to determine how long a word line is activated.

The refresh control circuit 316 (e.g., 116 of FIG. 1 and/or 254 of FIG. 2) may include an RHR state control circuit 342, an aggressor address register 344, and a refresh address generator 350. The RHR state control circuit 342 may receive the REF signal from the DRAM interface and the Agg signal from the counter control circuit 328 (e.g., 134 of FIG. 1 and/or 250 of FIG. 2). The RHR state control circuit 342 may provide an active signal RHR to indicate that a targeted refresh operation, such as a row hammer refresh should occur. A row hammer refresh, for example, may refresh of the victim rows corresponding to an identified aggressor row. The RHR state control circuit 342 may also provide an active internal refresh signal IREF, to indicate that a normal refresh operation should occur. The normal refresh signal REF may be periodically activated and may be used to control the timing of refresh operations. The signals RHR and IREF may be activated such that they are not active at the same time or in other words are not both at a high logic level at the same time.

The memory device may carry out a sequence of normal refresh operations in order to periodically refresh the rows of the memory device. The RHR signal may be activated in order to indicate that the device should refresh a particular targeted row, such as a victim row, instead of an address from the sequence of refresh addresses. The RHR state control circuit 342 may use internal logic to provide the active RHR signal. The RHR state control circuit 342 may provide the active RHR signal based on certain number of activations of REF. Additionally or alternatively, the RHR state control circuit 342 may activate the RHR signal responsive to receiving an active Agg signal from the count control circuit 328 (e.g., 134 of FIG. 1 and/or 250 of FIG. 2). The active Agg may trigger the refresh control circuit 316 (e.g., 116 of FIG. 1 and/or 254 of FIG. 2) to cause a targeted refresh operation to be performed outside the time period of a regularly scheduled refresh operation.

Responsive to an activation of RHR, the aggressor address register 344 may provide an aggressor address HitXADD, and the refresh address generator 350 may provide a refresh address RXADD, which may be one or more victim addresses associated with HitXADD. Responsive to IREF, the refresh address generator 350 may provide a normal refresh address as the refresh address RXADD. The row decoder 308 (e.g., 108 of FIG. 1 and/or 234 of FIG. 2) may perform a refresh operation responsive to the refresh address RXADD and the targeted refresh signal RHR. The row decoder 308 (e.g., 108 of FIG. 1 and/or 234 of FIG. 2) may perform a normal refresh operation based on the refresh address RXADD and the internal refresh signal IREF.

The aggressor address register 344 may store one or more row addresses which have been identified as aggressor addresses by the counter control circuit 328 (e.g., 134 of FIG. 1 and/or 250 of FIG. 2). Responsive to the command signal Agg from the counter control circuit 328 (e.g., 134 of FIG. 1 and/or 250 of FIG. 2), the aggressor address register 344 may store the current row address XADD which is being accessed. The aggressor address register 344 may provide the stored address as a match address HitXADD to the refresh address generator 350, which may calculate one or more victim addresses associated with the match address HitXADD.

The refresh address generator 350 may receive the targeted refresh signal RHR and the match address HitXADD. The match address HitXADD may represent an aggressor row. The refresh address generator 350 may determine the locations of one or more victim rows based on the match address HitXADD and provide them as the refresh address RXADD. The victim rows may include rows which are physically adjacent to the aggressor row or rows (e.g., HitXADD+1 and HitXADD−1). Other relationships between victim rows and the identified aggressor rows may also or alternatively be used.

The refresh address generator 350 may determine the value of the refresh address RXADD based on the targeted refresh signal RHR and the internal refresh signal IREF. When the signal IREF is active, the refresh address generator 350 may provide one of a sequence of refresh addresses. When the signal RHR is active, the refresh address generator 350 may provide a targeted refresh address, such as a victim address, as the refresh address RXADD. Multiple targeted refresh addresses may be provided for a refresh operation. For example, for a multi pump refresh operation, a different targeted refresh address may be provided for each pump (e.g., HitXADD+1 and HitXADD−1).

The row decoder 308 (e.g., 108 of FIG. 1 and/or 234 of FIG. 2) may perform one or more operations on the memory array 318 (e.g., 118 of FIG. 1 and/or 200 of FIG. 2) based on the received signals and addresses. For example, responsive to the activation signal ACT and the row address XADD and IREF and RHR being inactive, the row decoder 308 (e.g., 108 of FIG. 1 and/or 234 of FIG. 2) may direct one or more access operations, such as a read operation, on the specified row address XADD. Responsive to the RHR signal being active, the row decoder 308 (e.g., 108 of FIG. 1 and/or 234 of FIG. 2) may refresh the refresh address RXADD. The refresh control circuit 316 is provided merely as an example, and other types of refresh control circuits may be used in other embodiments.

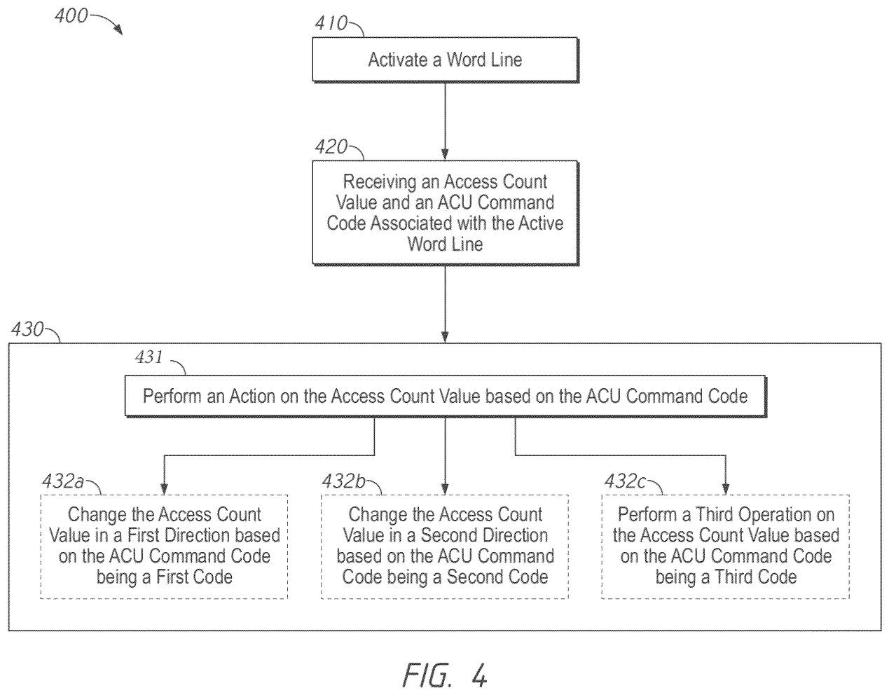

FIG. 4 is a flow chart of an example ACU operation based on an ACU command code according to some embodiments of the present disclosure. The flow chart 400 of FIG. 4 may, in some embodiments, be implemented by one or more of the apparatuses or systems described herein. For example, method 400 may be performed by the semiconductor device 100 of FIG. 1 and/or the counter control circuit 134 of FIG. 1, 250 of FIG. 2, and/or 328 of FIG. 3 during an ACU operation.

The method 400 may include box 410, which describes activating a word line. For example, the method 400 may include a memory device (e.g., 100 of FIG. 1) receiving an access command, such as an activation command ACT or a pre-charge command PRE, and an address from a controller. For example, the command address input circuit (e.g., 102 of FIG. 1) may receive the command and address from the controller. The command address input circuit (e.g., 102 of FIG. 1) may transmit the command and address to a command decoder (e.g., 106 of FIG. 1) and an address decoder (e.g., 104 of FIG. 1), respectively. The command decoder (e.g., 106 of FIG. 1) and the address decoder (e.g., 104 of FIG. 1) may then cause the row associated with the address to be activated or pre-charged based on the command received from the controller.

Box 410 is followed by box 420, which describes reading an access count value and an ACU command code associated with the active word line. For example, the access count value (e.g., XCount) stored in the counter memory cells (e.g., 126 of FIG. 1, 226 of FIG. 2, and/or 326 of FIG. 3) associated with the active word line may be received by a counter control circuit (e.g., 134 of FIG. 1, 250 of FIG. 2, and/or 328 of FIG. 3) and the ACU command code (e.g., ACU_CMD) stored in the ACU command memory cells (e.g., 128 of FIG. 1, 260 of FIG. 2, and/or 340 of FIG. 3) associated with the active word line may be read by the ACU command circuit (e.g., 136 of FIG. 1, 252 of FIG. 2, and/or 360 of FIG. 3).

Box 420 is followed by box 430, which describes performing an action on the access count value based on the value of ACU command code. In some embodiments, the action may be an ACU operation. For example, the value of the ACU command code may determine an ACU operation next performed by the counter control circuit (e.g., 136 of FIG. 1, 252 of FIG. 2, and/or 328 of FIG. 3) on the access count value (e.g., XCount) stored in the counter memory cells (e.g., 126 of FIG. 1, 226 of FIG. 2, and/or 326 of FIG. 3) associated with the active word line. In some embodiments, the ACU operation performed may be one of several possible operations based on the type of ACU command code (e.g., ACU_CMD). For example, there may be three different ACU operations based on the three different values of ACU command codes. In other embodiments, there may be more or fewer ACU operations and ACU command codes. The dashed boxes 432a-432c in box 430 of 431 FIG. 4 show the different ACU operations that may be performed based on the value of the ACU command code received in box 420.

Box 431 may be followed by box 432a, which describes changing the access count value in a first direction based on the value of the ACU command code being a first code. For example, the first ACU command code (e.g., ACU_CMD) may be a normal command code and the ACU operation performed by the counter control circuit (e.g., 136 of FIG. 1, 252 of FIG. 2, and/or 328 of FIG. 3) responsive to the value of the ACU command code may cause the access count value (e.g., XCount) to be incremented. In some embodiments, the ACU command code (e.g., ACU_CMD) may be set to the normal code if the memory device (e.g., 100 of FIG. 1) is operating in a normal mode, for example when the memory device is not in a refresh mode or an ACI mode. In some embodiments, the ACU command code (e.g., ACU_CMD) may be set to the normal code after a second or third type of ACU operation is performed based on a second or third ACU command code (e.g., ACU_CMD).

Box 431 may be followed by box 432b, which describes changing the access count value in a second direction based on the value of the ACU command code being a second code. For example, the ACU command code (e.g., ACU_CMD) may be a refresh code and the type of ACU operation performed by the counter control circuit (e.g., 136 of FIG. 1, 252 of FIG. 2, and/or 328 of FIG. 3) responsive the value of the ACU command code may cause the access count value (e.g., XCount) to be decremented. In some embodiments, the amount to be decremented may be a predetermined or preset amount. In some embodiments, if the amount to be decremented is greater than the access count value (e.g., XCount), the counter control circuit (e.g., 136 of FIG. 1, 252 of FIG. 2, and/or 328 of FIG. 3) may cause a value of “0” to be written to the counter memory cells (e.g., 126 of FIG. 1, 226 of FIG. 2, and/or 326 of FIG. 3). In some embodiments, the updated access count value (e.g., XCount′) may also be incremented and written back to the counter memory cells (e.g., 126 of FIG. 1, 226 of FIG. 2, and/or 326 of FIG. 3).

Box 431 may be followed by box 432c, which describes performing a third operation on the access count value based on the value of the ACU command code being a third code. In some embodiments, the third ACU command code (e.g., ACU_CMD) may be an initialization code. For example, the ACU command code (e.g., ACU_CMD) may be set to the initialization code while the memory device (e.g., 100 of FIG. 1) is in an ACI mode. Responsive to the value of the ACU command code (e.g., ACU_CMD) being the initialization code, the counter control circuit (e.g., 136 of FIG. 1, 252 of FIG. 2, and/or 328 of FIG. 3) may initialize the access count value (XCount) by causing an initialization value (e.g., ACI_INT) to be written to the counter memory cells (e.g., 126 of FIG. 1, 226 of FIG. 2, and/or 326 of FIG. 3). In some embodiments, the access count value (e.g., XCount) may be incremented after being initialized with the initialization value.

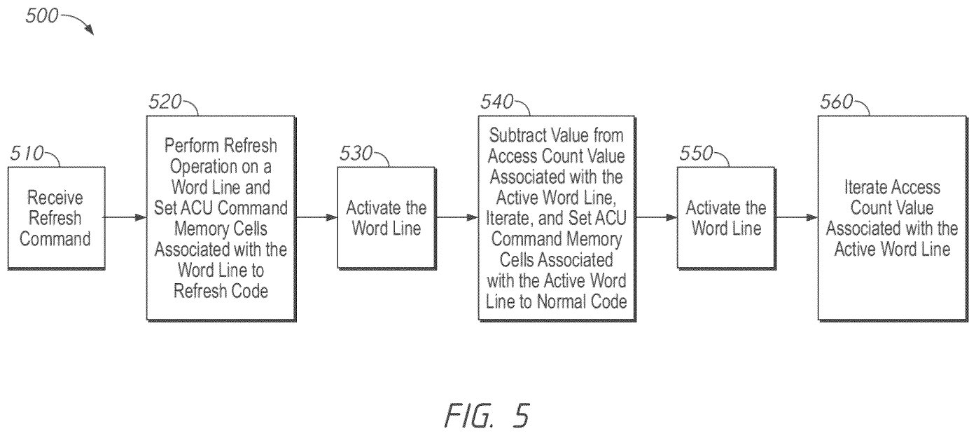

FIG. 5 is a flow chart of an example ACU command bit setting operation according to some embodiments of the present disclosure. The flow chart 500 of FIG. 5 may, in some embodiments, be implemented by one or more of the apparatuses or systems described herein. For example, method 500 may be performed by the semiconductor device 100 of FIG. 1 and/or the counter control circuit 134 of FIG. 1, 250 of FIG. 2, and/or 328 of FIG. 3 during an ACU operation.

Box 510 describes receiving a refresh command. In some embodiments, a memory device (e.g., 100 of FIG. 1) may receive the refresh command from a controller. In some embodiments, the memory device (e.g., 100 of FIG. 1) may enter a self-refresh mode and the refresh command may be an internal command. The method 500 may proceed to box 520.

Box 520 describes performing a refresh operation and setting ACU command memory cells to a refresh code. In some embodiments, the ACU command memory cells may include more than one or more bits. For example, responsive to the refresh command, a refresh control circuit (e.g., 116 of FIG. 1, 254 of FIG. 2, and/or 316 of FIG. 3) may perform a refresh operation on one or more word lines. Responsive to the refresh operation and/or the refresh command, an ACU command circuit (e.g., 136 of FIG. 1, 252 of FIG. 2, and/or 360 of FIG. 3) may set the ACU command memory cells (e.g., 128 of FIG. 1, 260 of FIG. 2, and/or 362 of FIG. 3) associated with the refreshed word line to a refresh code.

Box 530 describes activating the word line. At a time later, the refreshed word line may be activated, for example, in response to an access command such as an activation command ACT or a pre-charge command PRE. The access command may come from a controller, or the access command may be internally generated by the memory device (e.g., 100 of FIG. 1). The method 500 may proceed to box 540.

Box 540 describes subtracting a value from an access count value associated with the active word line, iterating it, and setting the ACU command memory cells associated with the active word line to a normal code. For example, responsive to the ACU command circuit (e.g., 136 of FIG. 1, 252 of FIG. 2, and/or 360 of FIG. 3) receiving the refresh code stored in the ACU command memory cells (e.g., 128 of FIG. 1, 260 of FIG. 2, and/or 362 of FIG. 3) associated with the active word line, the counter control circuit (e.g., 126 of FIG. 1, 250 of FIG. 2, and/or 328 of FIG. 3) may cause the access count value (e.g., XCount) associated with the active word line to be decremented by an amount. In some embodiments, the amount may be predetermined. Responsive to the activation of the word line, the counter control circuit (e.g., 126 of FIG. 1, 250 of FIG. 2, and/or 328 of FIG. 3) may iterate the decremented access count value (e.g., XCount), such as by incrementing it, and cause the updated access count value (e.g., XCount′) to be written to the counter memory cells (e.g., 126 of FIG. 1, 226 of FIG. 2, and/or 362 of FIG. 3) of the active word line. The ACU command circuit (e.g., 136 of FIG. 1, 252 of FIG. 2, and/or 360 of FIG. 3) may set the ACU command memory cells (e.g., 128 of FIG. 1, 260 of FIG. 2, and/or 362 of FIG. 3) associated with the active word line to a normal code responsive to the value being subtracted from the access count value (e.g., XCount). The method 500 may proceed to box 550.

Box 550 describes activating the word line. At a time later, the word line may be activated for a second time. For example, the word line may be activated responsive to a second activation command ACT or a second pre-charge command PRE. The word line may be activated responsive to normal operations of the memory device (e.g., 100 of FIG. 1). The method 500 may proceed to box 560.

Box 560 describes iterating the access count value associated with the active word line. For example, responsive to the second access command, the counter control circuit (e.g., 134 of FIG. 1, 250 of FIG. 2, and/or 328 of FIG. 3) may read the access count value (e.g., XCount) stored in the counter memory cells (e.g., 126 of FIG. 1, 226 of FIG. 2, and/or 326 of FIG. 3) associated with the active word line and the ACU command circuit (e.g., 136 of FIG. 1, 252 of FIG. 2, and/or 360 of FIG. 3) may read the ACU command code (e.g., ACU_CMD) stored in the ACU command memory cells (e.g., 128 of FIG. 1, 260 of FIG. 2, and/or 362 of FIG. 3) associated with the active word line. The ACU command code (e.g., ACU_CMD) may be a normal code. Responsive to the normal code, the counter control circuit (e.g., 126 of FIG. 1, 250 of FIG. 2, and/or 328 of FIG. 3) may cause the access count value (e.g., XCount) to be iterated. For example, the access count value (e.g., XCount) associated with the active word line may be incremented, such as by adding 1 or another amount. The updated access count value (e.g., XCount′) may be written to the counter memory cells (e.g., 126 of FIG. 1, 226 of FIG. 2, and/or 326 of FIG. 3) associated with the active word line.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the discussion herein is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array comprising a word line;
a first plurality of memory cells, wherein the first plurality of memory cells are counter memory cells configured to store an access count value associated with a number of times the word line has been accessed;
a second plurality of memory cells, wherein the second plurality of memory cells are access count update (ACU) command memory cells configured to store an ACU command code associated with a type of ACU operation to be performed on the access count value when the word line is accessed; and
a counter control circuit configured to:
perform a first type of ACU operation on the access count value based on a first value of the ACU command code stored in the ACU command memory cells when the word line is accessed, wherein the first type of ACU operation comprises changing the access count value in a first direction; and
perform a second type of ACU operation on the access count value based on a second value of the ACU command code stored in the ACU command memory cells when the word line is accessed, wherein the second type of ACU operation comprises changing the access count value in a second direction.

2. The apparatus of claim 1, wherein the counter control circuit comprises an ACU command circuit configured to:
read the ACU command code;
cause the counter control circuit to perform the first or second type of ACU operation based on the first or second value of the ACU command code being read; and
write the first value of the ACU command code to the ACU command memory cells after causing the counter control circuit to perform the second type of ACU operation.

3. The apparatus of claim 1, wherein the first value of the ACU command code is a normal code and the first type of ACU operation is to increment the access count value.

4. The apparatus of claim 1, wherein the second value of the ACU command code is a refresh code and the second type of ACU operation is to decrement the access count value by a decrement value.

5. The apparatus of claim 1, further comprising a third type of ACU operation performed responsive to a third value of the ACU command code.

6. The apparatus of claim 5, wherein the third value of the ACU command code is an initialization code and the third type of ACU operation is initializing the access count value to an initialization value.

7. The apparatus of claim 5, wherein the counter control circuit is further configured to change the ACU command code in the ACU command memory cells associated with the word line to the first value of the ACU command code after performing the second or third type of ACU operation.

8. A method comprising:
activating a word line;
receiving an access count value associated with the active word line;
receiving an access count update (ACU) command code associated with the active word line; and
performing an action on the access count value based on the value of the ACU command code.

9. The method of claim 8, wherein performing the action on the access count value comprises changing the access count value in a first direction when the ACU command code has a first value.

10. The method of claim 9, wherein the first value is a normal code and changing the access count value in the first direction comprises incrementing the access count value.

11. The method of claim 8, wherein performing the action on the access count value comprises changing the access count value is a second direction when the ACU command code has a second value.

12. The method of claim 11, wherein the second value is a refresh code and performing the action on the access count value comprises decrementing the access count value by a decrement value.

13. The method of claim 8, wherein performing the action on the access count value comprises performing a third operation on the access count value when the ACU command code has a third value.

14. The method of claim 13 wherein the third value is an initialization code and performing the action on the access count value comprises initializing the access count value to an initialization value.

15. The method of claim 8, further comprising changing the ACU command code to a first value after performing the action on the access count value based on the ACU command code having a value different than the first value.

16. A semiconductor device comprising:
a memory array comprising a word line;
a first plurality of memory cells, wherein the first plurality of memory cells are counter memory cells configured to store an access count value associated with a number of times the word line has been accessed;
a second plurality of memory cells, wherein the second plurality of memory cells are access count update (ACU) command memory cells configured to store a value of an ACU command code associated with a type of ACU operation to be performed on the word line when the word line is accessed;
a refresh control circuit configured to receive a refresh command and perform a refresh operation on the word line;
a counter control circuit configured to:
set the value of the ACU command memory cells associated with the word line to a refresh code responsive to the refresh command;
subtract a decrement value from the access count value associated with the word line responsive to an activation command on the word line when the value of the ACU command memory cells is the refresh code; and
set the value of the ACU command memory cells associated with the word line to a normal code responsive to subtracting the decrement value.

17. The semiconductor device of claim 16, wherein the counter control circuit is further configured to iterate the access count value associated with the word line responsive to a second activation command on the word line when the value of the ACU command memory cells is the normal code.

18. The semiconductor device of claim 16, further comprising an access count initialization (ACI) control circuit configured to:
receive an ACI command;
perform ACI operations on the word line responsive to the ACI command; and
transmit an ACI signal to the counter control circuit, wherein the counter control circuit is further configured to set the value of the ACU command memory cells associated with the word line to an initialization code.

19. The semiconductor device of claim 18, wherein the counter control circuit is further configured to:
initialize the access count value associated with the word line with an initialization value responsive to a second activation command; and
set the value of the ACU command memory cells associated with the word line to the normal code.

20. The semiconductor device of claim 18, wherein the counter control circuit is further configured to:
iterate the access count value associated with the word line after subtracting the decrement value from or initializing the access count value.
